(19) United States
(12) Patent Application Publication
(10) Pub. No.: US 2015/0262710 A1
(43) Pub. Date: Sep. 17, 2015

(54) METHOD AND SYSTEM FOR REDUCING MEMORY TEST TIME UTILIZING A BUILT-IN SELF-TEST ARCHITECTURE

(71) Applicant: LSI Corporation, San Jose, CA (US)

(72) Inventor: Sreejit Chakravarty, Mountain View, CA (US)

(73) Assignee: LSI Corporation, San Jose, CA (US)

(21) Appl. No.: 14/212,351

(22) Filed: Mar. 14, 2014

(51) Int. Cl. G11C 29/38; G11C 29/36

(52) U.S. Cl. CPC G11C 29/38; G11C 29/36; G11C 2029/3602

(57) ABSTRACT

Methods and systems for reducing memory test time utilizing a serial per march element communicating architecture. A small number of slow speed signals can be configured between a BIST wrapper and a BIST controller to transfer information in accordance with a BIST sequence that includes a number of march elements. An information transfer protocol can be implemented between the BIST wrapper and the BIST controller to transfer Information with respect to each march element that includes a number of BIST operations, address sequencing information, and data pattern. A command register can be loaded utilizing the slow speed signals and slow speed clock and content of the command register can be decoded. An encoded BIST operation can then be executed once for each BIST operation per march element. The serial per march element communicating architecture reduces test time as a communication overhead and a requirement for high speed wires are eliminated.

### FIELD OF THE INVENTION

Embodiments are generally related to electronic devices and circuits. Embodiments are also related to memory test pattern techniques. Embodiments are additionally related to BIST (Memory Built-In Self-Test) architectures. Embodiments are further related to the reduction of memory testing time.

### BACKGROUND

The testing of electronic devices represents a portion of the manufacturing process that is frequently under estimated in terms of the cost and effort required to obtain reliable data about the proper functionality and reliability of the manufactured device. As the density of memories increases, unwanted interference between cells and coupling noise between bit-lines becomes significant, frequently requiring parallel testing. The testing of high-density memories for a high-degree of fault coverage requires either a relatively large number of test vectors or a significant amount of additional test circuitry.

A BIST (Built-In Self-Test) is a mechanism that permits a machine to test itself. The main purpose of a BIST is to reduce complexity, and thereby decrease the cost of and reliance upon external (i.e., pattern-programmed) test equipment. BIST reduces test-cycle duration and the complexity of the test/probe setup by reducing the number of I/O signals that must be driven/examined under tester control which lead to a reduction in hourly charges for automated test equipment (ATE) service. Built-in self-test mechanism can be employed to make faster, less-expensive integrated circuit manufacturing tests.

FIG. 1 illustrates a block diagram of a memory test pattern structure 100 with respect to a BIST controller. The memory test pattern 100 can be divided into three parts: a pattern prefix phase 105, a BIST run 110, and a pattern suffix phase 115. In the pattern prefix phase 105, a test parameter can be set up by loading registers within a BIST wrapper and can be done by the memory BIST controller. The BIST run 110 shown in FIG. 1 is an example of an actual test run that accesses the memories being tested.

The wrapper reads data from and writes data into the memory in a specific order. This sequence can be referred to as the BIST sequence. In the suffix phase 115, the results of the BIST run status register, diagnostic information, etc., can be read. The total time to execute a pattern includes time for each of these three phases 105, 110, and 115. The time for each phase depends on memory DFT architecture. The time for the BIST run phase 110, in addition to the DFT architecture, also dependents on the BIST sequence.

FIG. 2 illustrates a BIST sequence 150 that includes a number of March Elements.

FIGS. 3A and 3B illustrate a prior art parallel communicating architecture (PCA) 200 depicting connections between the BIST controller 210 and BIST wrapper 215. The parallel communicating architecture (PCA) 200 includes the BIST controller 210 and a number of BIST wrappers 215. Signals wr_se, wr_si, wr_so, sel_chain with respect to the BIST wrappers 215 can be employed to serially load data into various wrapper registers during the prefix phase 105 utilizing a slow clock. The signals wr_se, wr_si, wr_so, sel_chain can also be employed to read out the results in the suffix phase 115.

The signal group rscen, rscin, rscout can be employed to load/unload memory repair data. Signal wr_dm0, wr_dm1, wr_dm2, BISTen differentiates between various test modes and the signal BISTen is set to 1 for memory test and the signals addr_mode, opcode, t_data, t_data_sh, t_addr are high speed signals that toggle at high speed. Referring to a march element 200 as shown in FIG. 2, opcode can transition at speed between different memory operations like WTM, R, WTM, and RM0 for each address in the memory. For each address in the memory, t_addr will change at speed, sweeping the entire address space, for each memory location and t_data, t_data_sh changes once per march element. Note that the overhead time 105 dominates for PLL based BIST runs 110. For memories with a large data bus and a small number of words, the overhead 105 is significantly larger than the BIST run time 110.

The test time can be calculated utilizing M=number of memory address bits, T=fast dock period, N=number of memory words, W=number of BIST wrappers controlled by the BIST controller 210, and G=number of BIST controller groups. For example, consider W=20, T=2 ns, G=50, and 38N BIST operations, connections=M+10+common, common=W+13=33, High speed=M+10 and overhead=10 ms. For N=16K, M=14 the test time can be calculated as shown below in equation (1).

[38N*T+10ms]*G=11.29*Gms=11.4*50ms=564.5ms=0.57s (non_pll,20Mhz test dock),[38*18384*50ns+10ms]*50 (1)

For N=512, M=9 the test time can be calculated as follows.

(38*512*2ns+10ms)*50=10.04*50ms=501ms=0.5s(non_pll,20Mhz test dock),[38*512*50ns+10ms]*50=549ms=0.55s (2)

The problem associated with such PCA architecture 200 is that the information about each operation is transferred on a per test clock cycle basis over high speed signals.

FIGS. 4A and 4B illustrate connections between the BIST controller 210 and the BIST wrapper 215 for an example serial per address communicating architecture 250 (SPACA). Signals wr_se, wr_si, wr_so, sel_chain can be employed to serially load data into various wrapper registers during the prefix phase 105 using a slow clock. The signals are also employed to read out the result in the suffix phase 115. Signal group rscen, rscin, rscout can be employed to load/unload memory repair data (not shown). wr_dm0, wr_dm1, wr_dm2, BISTen differentiates between various test modes. The signal BISTen is set to 1 for memory test. Slow speed signals cmd_se, cmd_si, force_scan replaces high-speed signals in the PCA architecture 200 shown in FIG. 3. FIG. 4 represents one cmd_se signal per wrapper. However, cmd_se for identical wrappers can be merged. Slow speed signals cmd_si, cmd_se, and the slow speed dock (WRCK) can be employed to load a command register.

FIG. 5 illustrates a structure of a command register 300 with respect to the SPACA architecture 250. Once the content of the register 300 is loaded, the scan_force signal can be pulsed and the operation is executed for the memory address pointed to by a TADDR field. FIG. 6 illustrates a command register transfer sequence with respect to the SPACA architecture 250. The 4 LSB bits can be first broadcasted to all the BIST wrappers 215. After that, 4 bits are transferred to one BIST wrapper 215 at a time. This is driven by the WRCK (or slow clock). Test Time for the BIST run 110 can be computed as follows. Overhead for prefix and suffix phase 105 and 115 is 10 ms and 1 slow clock to execute the BIST instruction and 3 dock cycles between loading of successive command register loading phase can be assumed.

Total=[38*N*[M+11+4]*S+10ms]*G=[38NS[M+15]+10ms]G (3)

For example, if N=16K, M=14 the test time can be calculated as follows.

[38*18384*50*29ns+10ms]*50=[1012958400ns+10ms]*50=1013*50ms=50.65s (4)

For example, if N=512, M=9 the test time can be calculated as follows.

[38*512*50*24ns+10ms]*50=[23347200ns+10ms]*50=33.3*50ms=1.65s (5)

In SPACA architecture 250, information about each BIST operation, per memory address location can be transferred utilizing the slow speed signals. The information in SPACA architecture 250 can be transferred for each address and each operation. The communication overhead for the PCA architecture 200 and SPACA architecture 250 is large and increases time and requires high speed wires.

Based on the foregoing, it is believed that a need exists for an improved system and method for reducing memory test time utilizing a built-in self-test architecture, as described in greater detail herein.

### SUMMARY

The following summary is provided to facilitate an understanding of some of the innovative features unique to the disclosed embodiment and is not intended to be a full description. A full appreciation of the various aspects of the embodiments disclosed herein can be gained by taking the entire specification, claims, drawings, and abstract as a whole.

It is, therefore, one aspect of the disclosed embodiments to provide for improved memory test pattern techniques.

It is another aspect of the disclosed embodiments to provide for an improved memory BIST (Built-in Self-Test) mechanism.

It is further aspect of the disclosed embodiment to provide methods and systems for reducing the memory test time utilizing a serial per march element communicating architecture.

The aforementioned aspects and other objectives and advantages can now be achieved as described herein. Methods and systems are disclosed for reducing memory test time utilizing a serial per march element communicating architecture. A small number of slow speed signals can be configured between a BIST wrapper and a BIST controller to transfer information in accordance with a BIST sequence that includes a number of march elements. An information transfer protocol can be implemented between the BIST wrapper and the BIST controller to transfer Information with respect to each march element that includes a number of BIST operations, address sequencing information, and data pattern. A command register can be loaded utilizing the slow speed signals and slow speed clock and content of the command register can be decoded. An encoded BIST operation can then be executed once for each BIST operation per march element. The serial per march element communicating architecture reduces test time as a communication overhead and a requirement for high-speed wires are eliminated.

A scan force signal can be pulsed and an operation is executed for each march element once the content of the command register structure that includes a shorter BIST run is loaded. The BIST wrapper receives a memory access command from the BIST controller, in accordance with the BIST sequence via the slow speed signals and executes a memory accesses and comparison operation. The BIST controller is responsible for controlling a set of BIST wrappers in its control and sequences through the BIST sequence and reads various status and diagnostic information from the individual BIST wrappers.

During the BIST run phase, the BIST controller breaks up the BIST sequence into individual memory BIST operations. This information can be communicated to the BIST wrapper via the information transfer protocol. The information transfer protocol determines the signals running between the BIST controller and the BIST wrappers. The BIST controller reads the result of the BIST run from the BIST wrappers. For example, 33 bits of the command register can be transferred utilizing the slow WRCK clock. The serial per march element communicating architecture eliminates the need for high-speed signal, thus reducing routing overhead of PCA and simplifying timing closure.

### BRIEF DESCRIPTION OF THE FIGURES

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a block diagram of a memory test pattern structure;

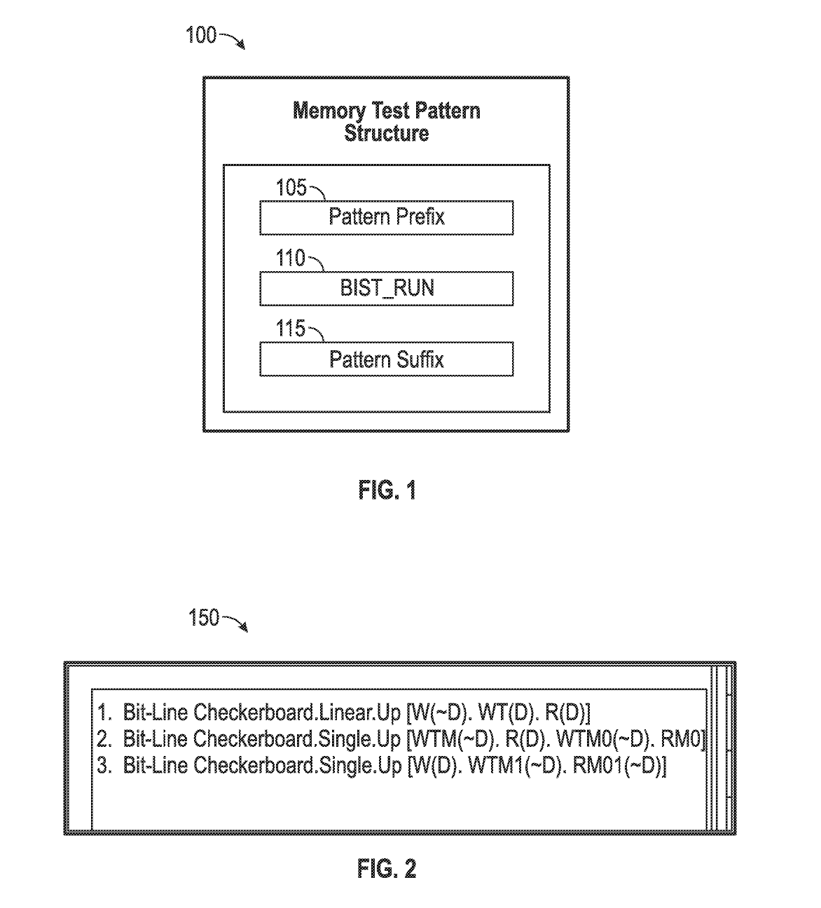

FIG. 2 illustrates a BIST sequence that includes a number of march elements;

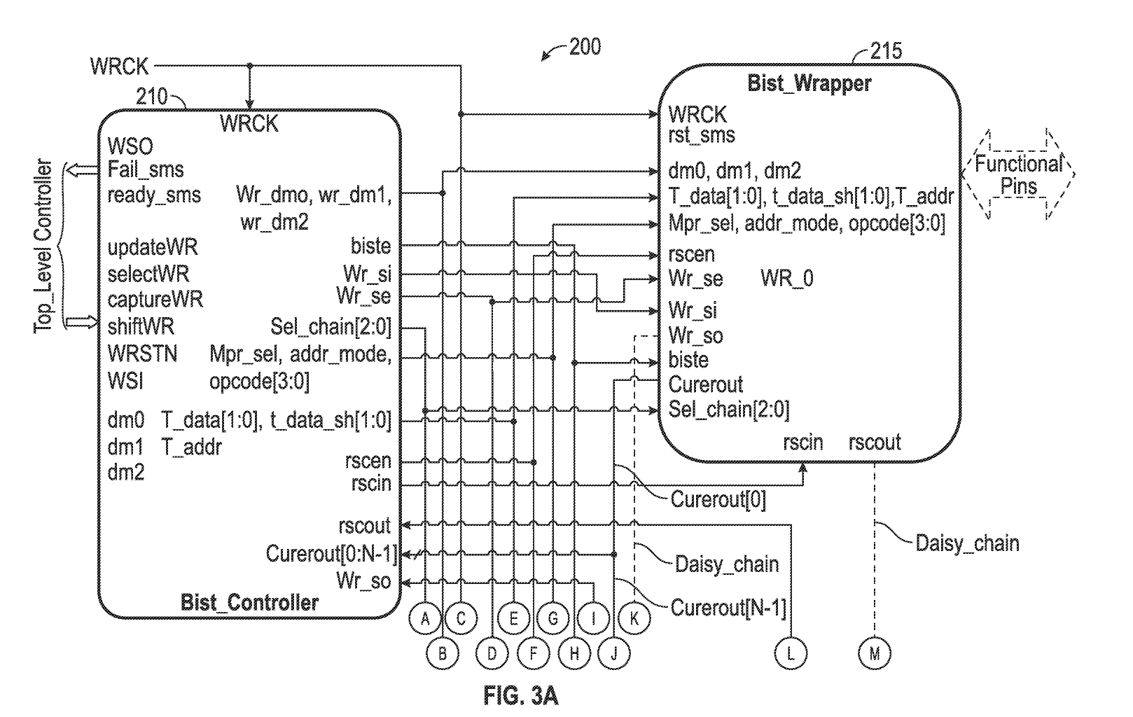

FIGS. 3A and 3B illustrate a prior art parallel communicating architecture (PCA) depicting connections between BIST controller and BIST wrapper;

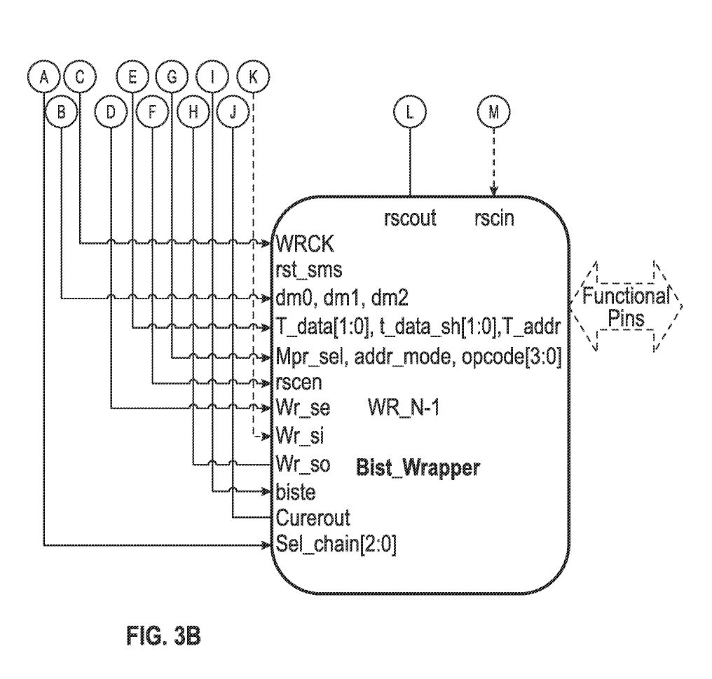

FIGS. 4A and 4B illustrate a prior art serial per address communicating architecture (SPACA) depicting connections between BIST controller and BIST wrapper;

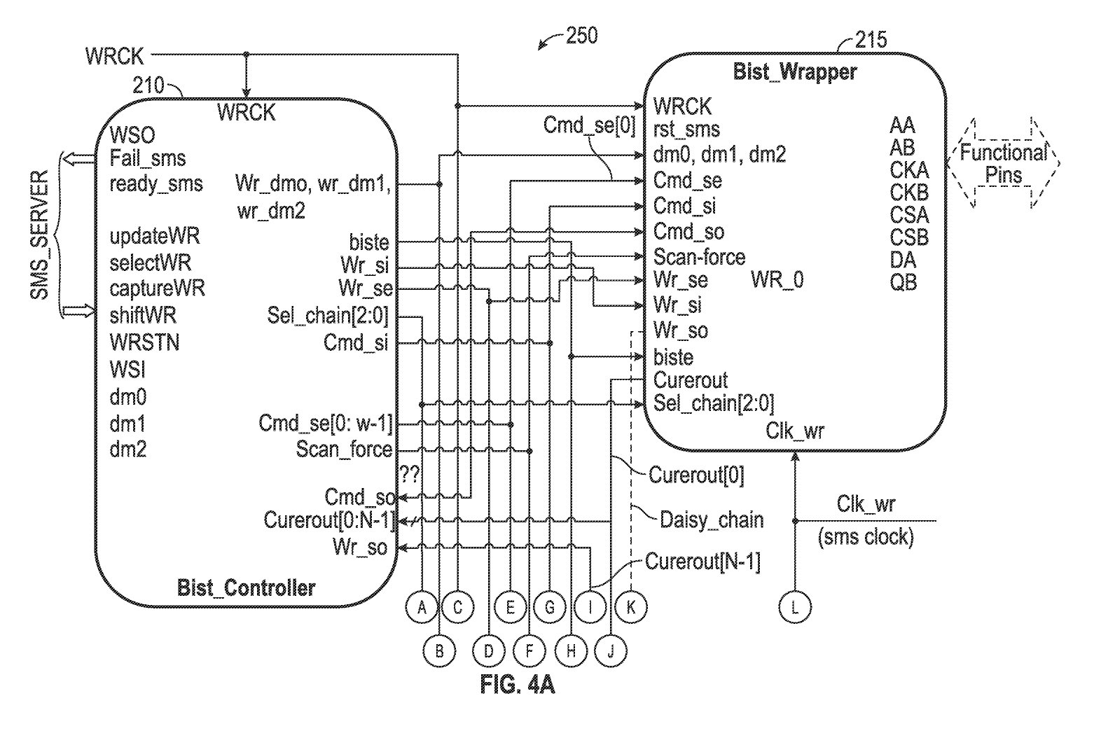

FIG. 5 illustrates a command register of the serial per address communicating architecture;

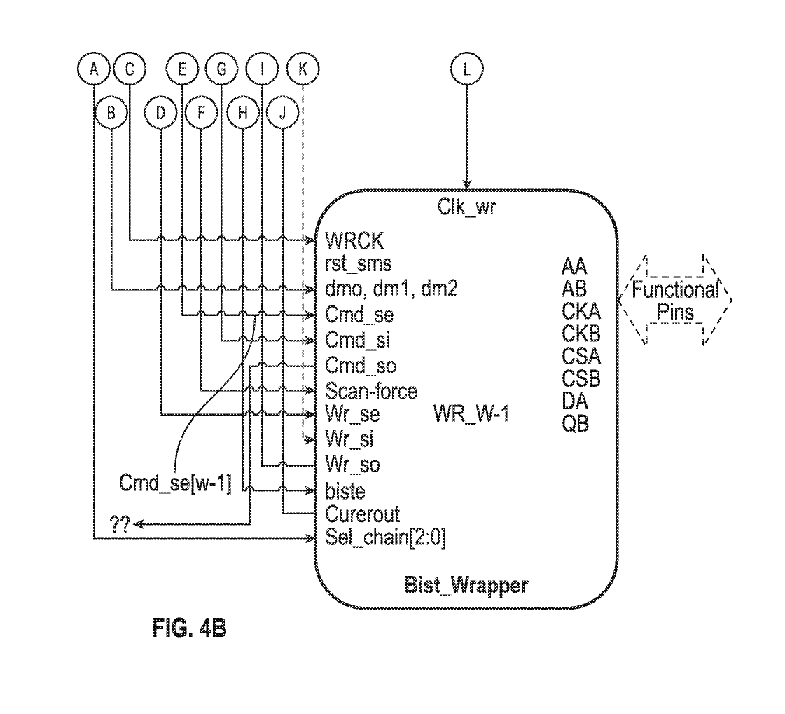

FIG. 6 illustrates a command register transfer sequence of the serial per address communicating architecture;

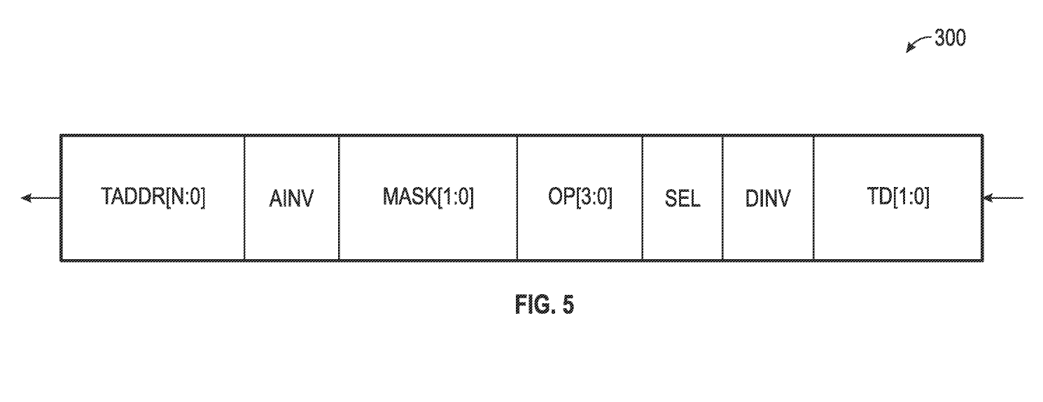

FIG. 7 illustrates a serial per march element communicating architecture (SPMCA), in accordance with the disclosed embodiments;

FIG. 8 illustrates a high level flow chart of operations illustrating logical operational steps of a method for reducing memory test time utilizing the serial per march element communicating architecture, in accordance with the disclosed embodiments;

FIGS. 9-11 illustrate BIST sequences that includes a number of march elements, in accordance with the disclosed embodiments;

FIG. 12 illustrates a block diagram determining total test time for a memory test, in accordance with the disclosed embodiments;

FIG. 13 illustrates a command register of the serial per march element communicating architecture, in accordance with the disclosed embodiments; and

FIG. 14 illustrates a table comparing test time and a number of high-speed connections between the PCA, SPACA, and SPMCA, in accordance with the disclosed embodiments.

### DETAILED DESCRIPTION

The particular values and configurations discussed in these non-limiting examples can be varied and are cited merely to illustrate at least one embodiment and are not intended to limit the scope thereof.

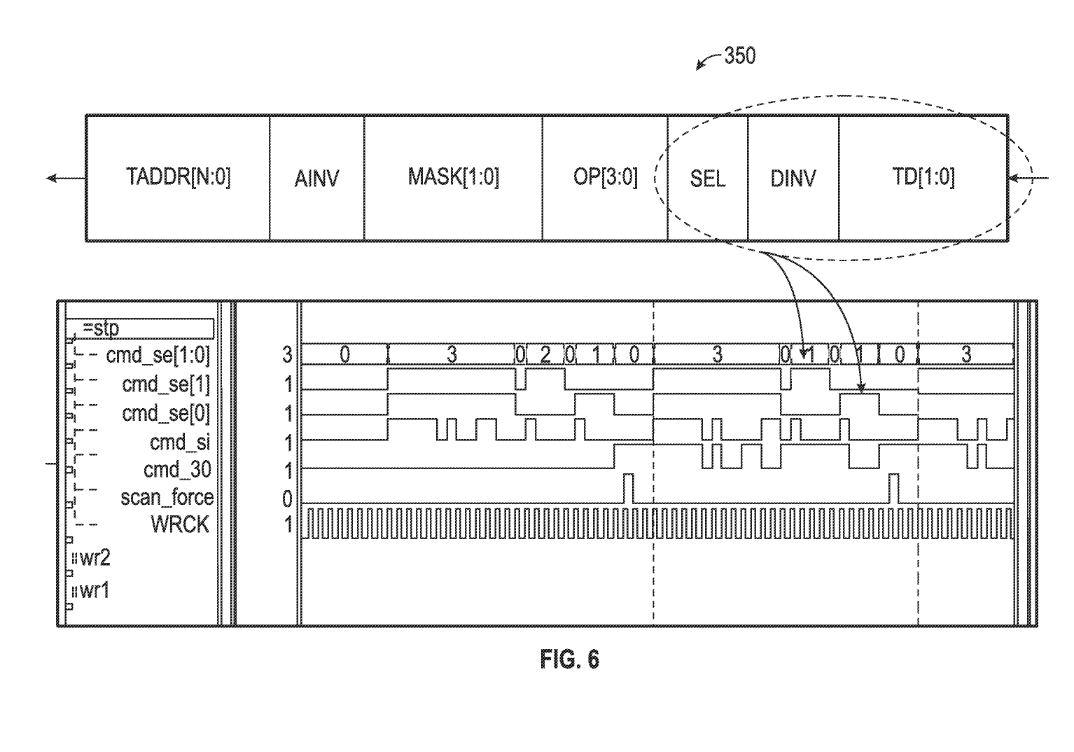

FIG. 7 illustrates a serial per march element communicating architecture 700, in accordance with the disclosed embodiments. The serial per march element communicating architecture 700 generally includes a top-level controller 705, a BIST controller 710, an information transfer protocol 725, and a number of BIST wrappers 735. Each BIST wrapper 735 includes a sequencer 740, and a set of one or more memory interfaces 745 and one or more respective memory modules 750. In particular, electronic device includes the BIST controller 710, which provides a centralized, high-level control over the testing of devices. In general, the BIST controller 710 provides and communicates test algorithms to the sequencer 740 for application to devices. The top level controller 705 communicates with the BIST controller 710 and loads setup information for BIST sequence 740 to be executed. This can include information regarding the memories to be disabled etc.

The BIST controller 710 communicates algorithms to the sequencers 740 as a set of commands that conform to a generic and flexible command protocol. Each command specifies an operational code and a set of parameters without regard to the physical characteristics or timing requirements of memory modules 750. The sequencers 740 interpret and execute the test algorithms provided by the BIST controller 710. In particular, the sequencers 740 receive high-level commands from the BIST controller 710 that define a complete BIST algorithm. A single command, for example, may define a particular bit pattern to be written over a range of one or more addresses. In response to the commands, each of the sequencers 740 issues one or more sequences of memory operations to their respective memory interfaces 745 to perform the commands.

The memory interfaces 745 handle specific interface requirements for each of the memory modules 750. For example, each of the memory interfaces 745 may be designed in accordance with a particular signal interface requirement and physical characteristics of the memory modules 750. As a result, each memory interfaces 745 may be viewed as providing an interface “wrapper” around the particular interface signals, e.g., address, data, and control signals, for each respective memory module 750. The memory modules 750 may be any type of memory such as random access memory (RAM), read-only memory (ROM), Flash memory, dynamic random access memory (DRAM), SDRAM, RDRAM, DDR-RAM, combinations thereof, and the like, and the techniques described herein are not limited in this regard.

A small number of slow speed signals 715 can be configured between the BIST wrapper 735 and the BIST controller 710 to transfer information in accordance with the BIST sequencer 740 that includes a number of the march elements 730. The BIST wrapper 735 receives a memory access command from the BIST controller 710, in accordance with the BIST sequence via the slow speed signals 715 and executes the memory accesses and comparison operations. The BIST controller 710 is responsible for controlling a set of the BIST wrappers 735 in its control and sequences through the BIST sequence and reads the various status and diagnostic information from the individual BIST wrappers 735. During the BIST run phase 110, the BIST controller 710 breaks up the BIST sequence into individual memory BIST operations. This information can be communicated to the BIST wrapper 735 via the information transfer protocol 725.

The information to be communicated to the BIST wrapper 735 includes the following one or more BIST test operations to be performed in the march step, address information, addressing information—address count up, down, etc., memory disable information, etc. The information transfer protocol 725 can be implemented between the BIST wrapper 735 and the BIST controller 710 to transfer information with respect to each march element 730 that includes a number of BIST operations, address sequencing information, and data pattern.

The architecture 700 includes a command register 720 structure that includes a shorter BIST run 110 that accesses only a subset of the memory space. Once the content of the register 720 is loaded, a scan_force signal is pulsed and an operation can be executed for each march element 730. The information transfer protocol 725 determines the signals running between the BIST controller 710 and the BIST wrappers 735. The BIST controller 710 reads the result of the BIST run 110 from the BIST wrappers 735. For example, 33 bits of the command register 720 can be transferred utilizing the slow WRCK clock. The serial per march element communicating architecture 700 eliminates the need for high-speed signal, thus reducing routing overhead of PCA 200 and simplifying timing closure.

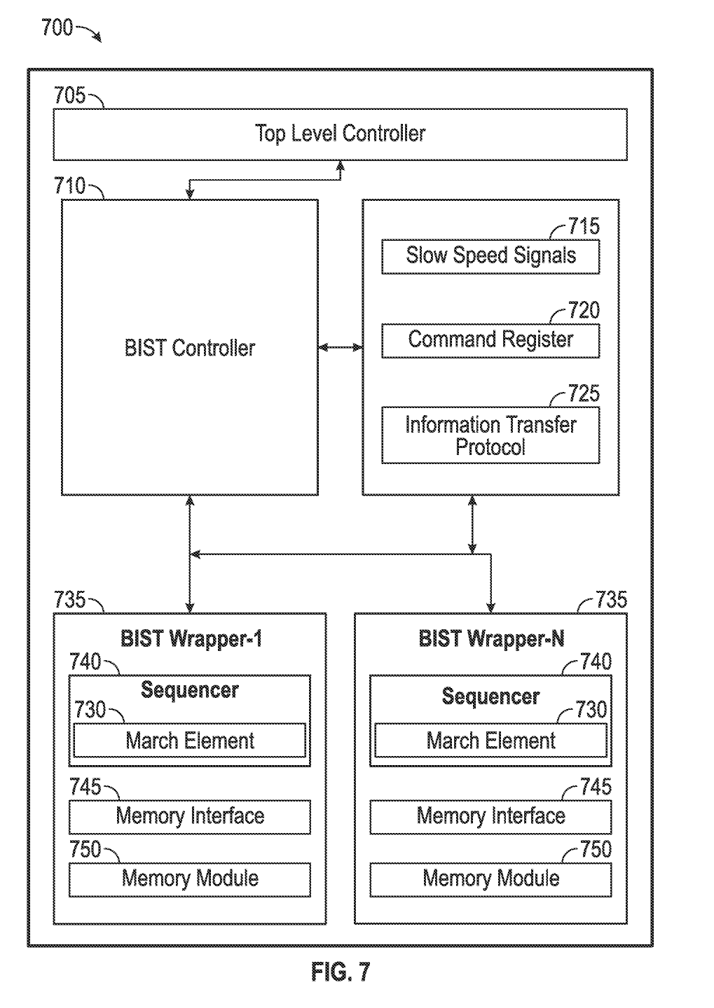

FIG. 8 illustrates a high level flow chart of operations illustrating logical operational steps of a method 800 for reducing memory test time utilizing the serial per march element communicating architecture 700, in accordance with the disclosed embodiments. The small number of slow speed signals 715 can be configured between the BIST wrapper 735 and the BIST controller 710 to transfer information in accordance with the BIST sequence that includes the number of march elements 730, as mentioned at block 810.

The information transfer module 725 can be implemented between the BIST wrapper 735 and the BIST controller 710 to transfer Information with respect to each march element 730 that includes the number of BIST operations, address sequencing information, and data pattern, as described at block 820. The command register 720 can be loaded using the slow speed signals 715 and slow speed dock and content of the command register 720 can be decoded, as indicated at block 830. The encoded BIST operation can be executed once for each BIST operation per march element 730, as shown at block 840. The serial per march element communicating architecture 730 reduces test time as the communication overhead and the requirement for high-speed wires are eliminated, as illustrated at block 850.

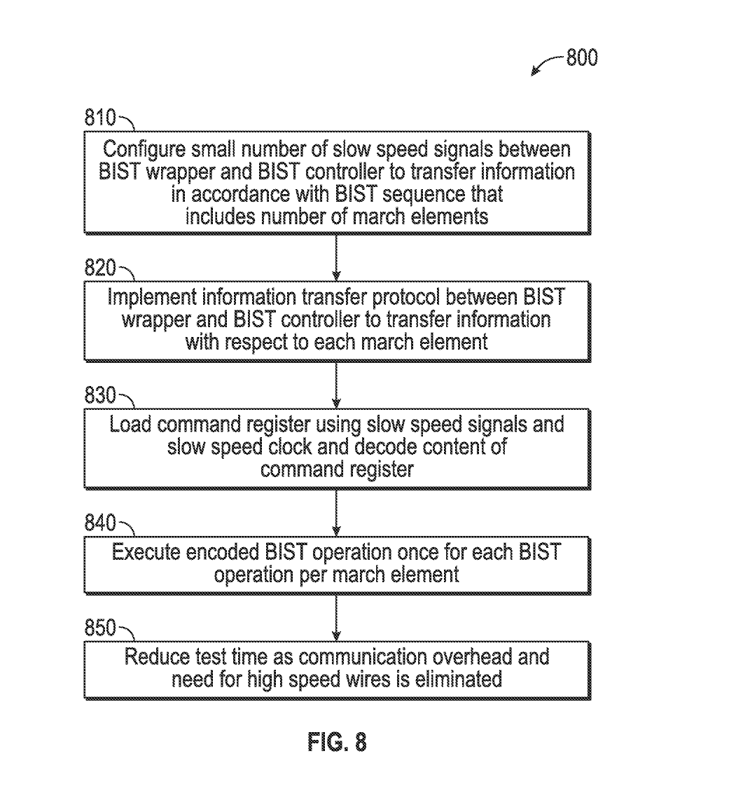

FIGS. 9-11 illustrate BIST sequences 860, 880, and 900 that include a number of march elements, in accordance with the disclosed embodiments. The BIST sequence 860, 880, and 900 generally includes a number of march elements. Each march element includes a number of BIST operations, address sequencing information, and data pattern. For example, FIG. 9 illustrates VLRF_23N7 BIST sequence utilized for certain memory types. The BIST sequence includes 11 march elements. For example, march element 3 includes three BIST operations (RWN, WR, RWN).

The operations can be defined as follows: RWN can be a back-to-back Read D and Write ˜D operations to similar address. WR can be a back-to-back Write D and Read ˜D operations to similar address. The data pattern to be used is “Bit-Line Checkerboard”. For RWN, the un-complemented bit-line checker board data is to be used. While for WR, RWN the complemented bit-line checkerboard data can be utilized. The address sequence starts from 0 and progresses up, linearly. For the sample calculations, the following three BIST sequences can be utilized. Where N refers to a number of words in the memory, 20N for VLRF_23N7 refers to the fact that the sequence accesses each memory location 20 times. If all 3 are utilized each memory location can be accessed 38 time.

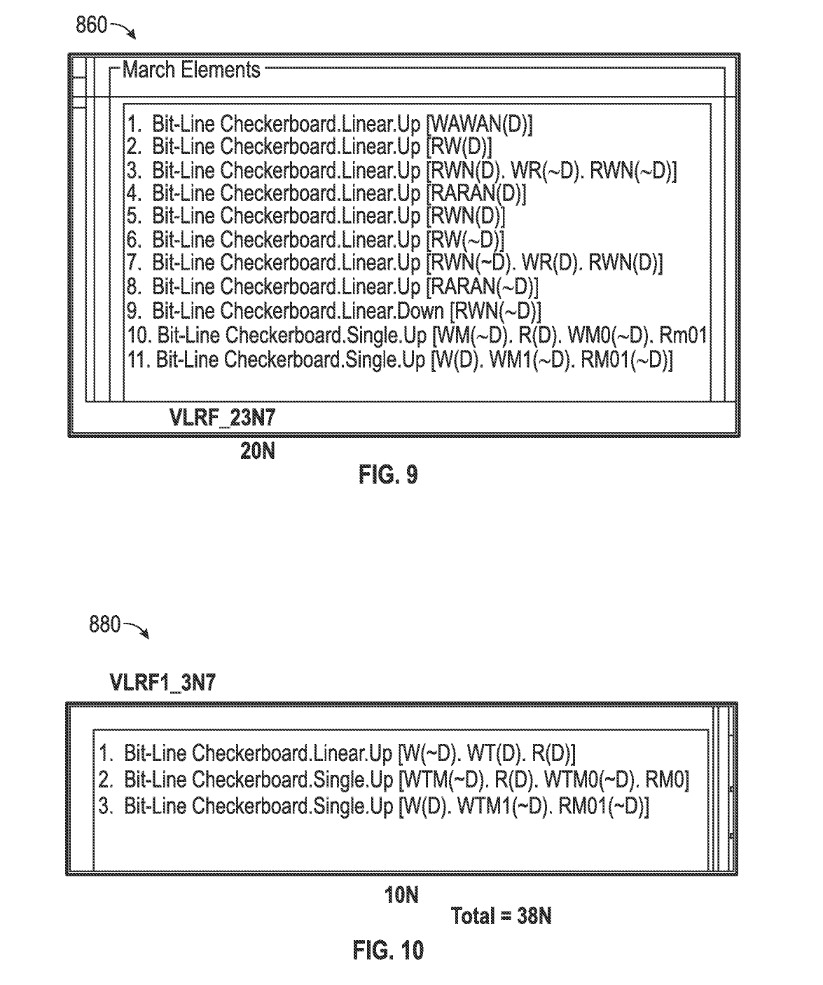

FIG. 12 illustrates a block diagram 930 determining total test time for testing the memory, in accordance with the disclosed embodiments. For example, a large design includes a large number of memory instances spread across the die. For a variety of reasons, which includes power consumption, routing congestion, clock domain, etc., all these memories cannot be tested simultaneously. The memories can be grouped into subgroups and one memory test can be applied per subgroup as the total memory test time can be calculated as shown below in equation (6):

Total memory test time=(10ms+BIST run(ms))*Number of memory subgroups (6)

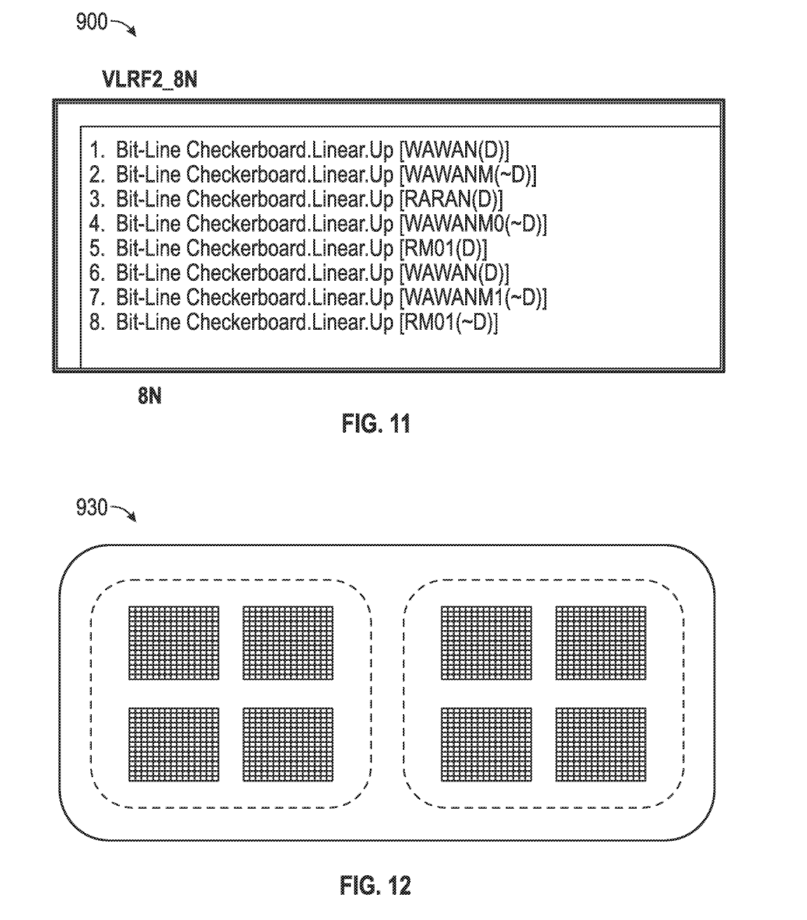

FIG. 13 illustrates the command register 720 of the serial per march element communicating architecture 700, in accordance with the disclosed embodiments. Once the content of this register 720 is loaded, the scan_force signal can be pulsed and the operation can be executed. For example, assume that each march element 730 includes a maximum of 5 BIST operations. Recall that VLRF_23N7, VLRF1_3N7 and VLRF2_8N has a total of 22 march elements 730 and 38 BIST operations. FBIST_RUN is a shorter BIST run 110 that accesses only a subset of the memory space, UPDN execute opcode with address incr from 0 to 2**M; else addr decrement starting from max.

ANIV represents control bit for the LSB of the test address to toggle in a back-to-back cycle operations. MASK[1:0] represents mask enable bits for all odd and even IOs or for left and right halves based on use_mask_on_we wrapper options and OP[0:3] represents test operation. The control bits generate read/write commands to support different single and back-to-back cycle operations. SEL represents Wrapper select and enable operation to be applied to the given wrapper. DINV represents pattern inverse control hit to invest test data for the second cycle operations. TD[1:0] represents the Test data.

Assume that each march element 730 has a maximum of 5 BIST operations. VLRF_23N7, VLRF_3N7 and VLRF2_8N has a total of 22 march elements 730 and 38 BIST operations. FBIST run is a shorter BIST run 110 that accesses only a subset of the memory space. For example, assume that the merged sequence of m (=2)2 march elements 730 can be utilized and 33 bits of the command register 720 can be transferred utilizing the slow WRCK clock. All but 4 bits can be broadcasted. The remaining 4 bits can be transferred to the W wrappers one at a time. The communication overhead can be calculated as shown below in equation (7):

Communication overhead=29+4*W WRCK cycles,per march element=(29+4*20)*50ns=5450ns=˜0.005ms,per march element.˜0.005*Q (7)

where Q represents the number of march elements=0.005*22 (for our example)=0.11 ms. The BIST operations requires 2**M*38*T where T=test dock cycle period=2 ns. Total time=(10 ms+0.11 ms+2**M*38*2 ns)*50=˜(10.11+(2**M*76)/10**6)*50 ms=˜45.21 s (for 1M memory). Since the communication overhead can be small, this essentially reduces to the PCA 200 test time. In addition, the need for high speed wires is also eliminated.

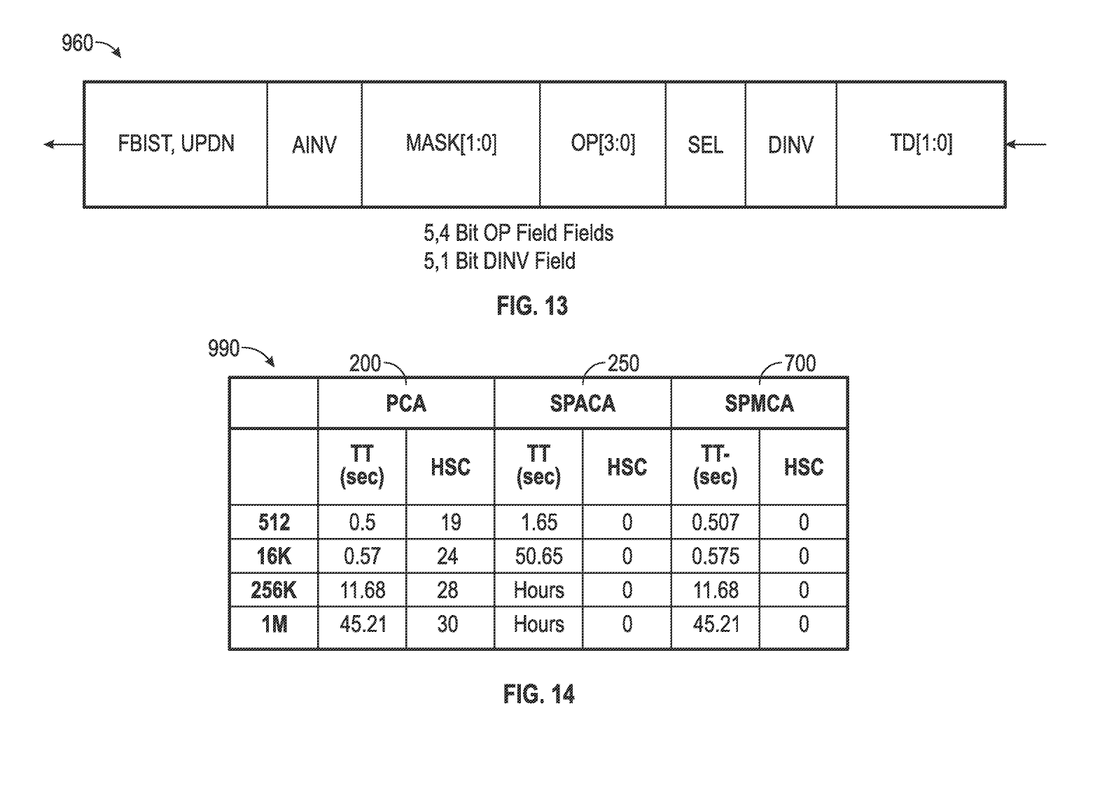

FIG. 14 illustrates a table comparing test time and a number of high speed connections between the PCA 200, SPACA 250, and SPMCA 700, in accordance with the disclosed embodiments. The SPMCA 700 transfers information regarding each march element 730, between the BIST wrapper 735 and the BIST controller 710 utilizing the slow speed signals 715. In PCA 200, information regarding each operation on a per test clock cycle basis can be transferred over high speed signals.

In SPACA 250, information about each BIST operation per memory address location can be transferred utilizing the slow speed signals 715. In FIG. 14, TT represents test time and HSC represents number of high speed connections. The SPMCA 700 match the test time of PCA 200 while eliminating the need for high speed connections. As shown in table 990 with increase in memory size SPMCA 700 becomes a better alternative to both PCA 200 and SPACA 250.

Based on the foregoing, it can be appreciated that a number of embodiments are disclosed, which are preferred and alternative. For example, in one embodiment, a method can be implemented for reducing memory test time. Such a method can include, for example, steps or logical operations such as assembling slow speed signals between a BIST wrapper and a BIST controller to transfer information in accordance with a BIST sequence that includes a plurality of march elements; facilitating an information transfer protocol between the BIST wrapper and the BIST controller to transfer the information with respect to each march element among the plurality of march elements; and loading a command register utilizing the slow speed signals and a slow BIST clock to decode a content of the command register so as to execute an encoded BIST operation once with respect to each BIST operation per march element.

In another embodiment, a step or logical operation can be provided for reducing a test time via the slow speed signals and the information transfer protocol. In yet another embodiment, the aforementioned march element can include at least one of, for example: a plurality of BIST operations, an address sequencing information, and a data pattern.

In still another embodiment, steps or logical operations can be provided for pulsing a scan force signal in order to execute an operation for each march element once a content of the command register structure that includes a shorter BIST run is loaded; receiving a memory access command from the BIST controller by the BIST wrapper in accordance with the BIST sequence via the slow speed signals; and executing a plurality of memory access and comparison operations.

In other embodiments, steps or logical operations can be provided for controlling a set of BIST through the BIST sequence by the BIST controller; and reading a plurality of status and diagnostic information from the BIST wrapper. In another embodiment, a step or logical operation can be implemented for separating the BIST sequence into at least one individual memory BIST operation during a BIST run phase by the BIST controller wherein the information is communicated to the BIST wrapper via the information transfer protocol. In another embodiment, steps or logical operations can be provided for determining a plurality of signals running between the BIST controller and the BIST wrapper by the information transfer protocol; and reading a result of the BIST run from the BIST wrapper utilizing the BIST controller.

In another embodiment, a system for reducing memory test time. Such a system can include, for example, a processor; and a computer-usable medium embodying computer program code, the computer-usable medium capable of communicating with the processor. The computer program code can include instructions executable by the processor and configured, for example, for assembling slow speed signals between a BIST wrapper and a BIST controller to transfer information in accordance with a BIST sequence that includes a plurality of march elements; facilitating an information transfer protocol between the BIST wrapper and the BIST controller to transfer the information with respect to each march element among the plurality of march elements; and loading a command register utilizing the slow speed signals and a slow BIST clock to decode a content of the command register so as to execute an encoded BIST operation once with respect to each BIST operation per march element.

In another embodiment, such instructions can be further configured for reducing a test time via the slow speed signals and the information transfer protocol. In another embodiment, the aforementioned march element can include one or more of, for example: a plurality of BIST operations, an address sequencing information, and a data pattern.

In still another embodiment, such instructions can be further configured for pulsing a scan force signal in order to execute an operation for each march element once a content of the command register structure that includes a shorter BIST run is loaded; receiving a memory access command from the BIST controller by the BIST wrapper in accordance with the BIST sequence via the slow speed signals; and executing a plurality of memory access and comparison operations.

In another embodiment, such instructions can be further configured for controlling a set of BIST through the BIST sequence by the BIST controller; and reading a plurality of status and diagnostic information from the BIST wrapper. In still another embodiment, such instructions can be further configured for separating the BIST sequence into at least one individual memory BIST operation during a BIST run phase by the BIST controller wherein the information is communicated to the BIST wrapper via the information transfer protocol.

In another embodiment, such instructions can be further configured for determining a plurality of signals running between the BIST controller and the BIST wrapper by the information transfer protocol; and reading a result of the BIST run from the BIST wrapper utilizing the BIST controller.

In yet another embodiment, a processor-readable medium storing code representing instructions to cause a process for reducing memory test time can be implemented. Such code can include code to, for example, assemble slow speed signals between a BIST wrapper and a BIST controller to transfer information in accordance with a BIST sequence that includes a plurality of march elements; facilitate an information transfer protocol between the BIST wrapper and the BIST controller to transfer the information with respect to each march element among the plurality of march elements; and load a command register utilizing the slow speed signals and a slow BIST clock to decode a content of the command register so as to execute an encoded BIST operation once with respect to each BIST operation per march element.

In another embodiment, such code can include code to reduce a test time via the slow speed signals and the information transfer protocol. In still another embodiment, the aforementioned march element can include one or more of, for example, one or more BIST operations, an address sequencing information, and a data pattern. In still another embodiment, such code can further include code to: pulse a scan force signal in order to execute an operation for each march element once a content of the command register structure that includes a shorter BIST run is loaded; receive a memory access command from the BIST controller by the BIST wrapper in accordance with the BIST sequence via the slow speed signals; and execute a one or more or a group of memory access and comparison operations.

In another embodiment such code can further include code to control a set of BIST through the BIST sequence by the BIST controller; and read a plurality of status and diagnostic information from the BIST wrapper. In yet another embodiment, such code can further include code to separate the BIST sequence into at least one individual memory BIST operation during a BIST run phase by the BIST controller wherein the information is communicated to the BIST wrapper via the information transfer protocol.

In yet another embodiment, such code can further include code to determine a plurality of signals running between the BIST controller and the BIST wrapper by the information transfer protocol; and read a result of the BIST run from the BIST wrapper utilizing the BIST controller.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

1. A method for reducing memory test time, said method comprising:
assembling slow speed signals between a BIST wrapper and a BIST controller to transfer information in accordance with a BIST sequence that includes a plurality of march elements;
facilitating an information transfer protocol between said BIST wrapper and said BIST controller to transfer said information with respect to each march element among said plurality of march elements; and
loading a command register utilizing said slow speed signals and a slow BIST clock to decode a content of said command register so as to execute an encoded BIST operation once with respect to each BIST operation per march element.

2. The method of claim 1 further comprising reducing a test time via said slow speed signals and said information transfer protocol.

3. The method of claim 1 wherein said march element comprises at least one of: a plurality of BIST operations, an address sequencing information, and a data pattern.

4. The method of claim 1 further comprising:
pulsing a scan force signal in order to execute an operation for each march element once a content of said command register structure that includes a shorter BIST run is loaded;
receiving a memory access command from said BIST controller by said BIST wrapper in accordance with said BIST sequence via said slow speed signals; and
executing a plurality of memory access and comparison operations.

5. The method of claim 1 further comprising:
controlling a set of BIST through said BIST sequence by said BIST controller; and
reading a plurality of status and diagnostic information from said BIST wrapper.

6. The method of claim 1 further comprising:
separating said BIST sequence into at least one individual memory BIST operation during a BIST run phase by said BIST controller wherein said information is communicated to said BIST wrapper via said information transfer protocol.

7. The method of claim 1 further comprising:
determining a plurality of signals running between said BIST controller and said BIST wrapper by said information transfer protocol; and
reading a result of said BIST run from said BIST wrapper utilizing said BIST controller.

8. A system for reducing memory test time, said system comprising:
a processor; and
a computer-usable medium embodying computer program code, said computer-usable medium capable of communicating with the processor, said computer program code comprising instructions executable by said processor and configured for:
assembling slow speed signals between a BIST wrapper and a BIST controller to transfer information in accordance with a BIST sequence that includes a plurality of march elements;
facilitating an information transfer protocol between said BIST wrapper and said BIST controller to transfer said information with respect to each march element among said plurality of march elements; and
loading a command register utilizing said slow speed signals and a slow BIST clock to decode a content of said command register so as to execute an encoded BIST operation once with respect to each BIST operation per march element.

9. The system of claim 8 wherein said instructions are further configured for reducing a test time via said slow speed signals and said information transfer protocol.

10. The system of claim 8 wherein said march element comprises at least one of: a plurality of BIST operations, an address sequencing information, and a data pattern.

11. The system of claim 8 wherein said instructions are further configured for:
pulsing a scan force signal in order to execute an operation for each march element once a content of said command register structure that includes a shorter BIST run is loaded;
receiving a memory access command from said BIST controller by said BIST wrapper in accordance with said BIST sequence via said slow speed signals; and
executing a plurality of memory access and comparison operations.

12. The system of claim 8 wherein said instructions are further configured for:
controlling a set of BIST through said BIST sequence by said BIST controller; and
reading a plurality of status and diagnostic information from said BIST wrapper.

13. The system of claim 8 wherein said instructions are further configured for separating said BIST sequence into at least one individual memory BIST operation during a BIST run phase by said BIST controller wherein said information is communicated to said BIST wrapper via said information transfer protocol.

14. The system of claim 8 wherein said instructions are further configured for:
determining a plurality of signals running between said BIST controller and said BIST wrapper by said information transfer protocol; and
reading a result of said BIST run from said BIST wrapper utilizing said BIST controller.

15. A processor-readable medium storing code representing instructions to cause a process for reducing memory test time, said code comprising code to:
assemble slow speed signals between a BIST wrapper and a BIST controller to transfer information in accordance with a BIST sequence that includes a plurality of march elements;
facilitate an information transfer protocol between said BIST wrapper and said BIST controller to transfer said information with respect to each march element among said plurality of march elements; and
load a command register utilizing said slow speed signals and a slow BIST clock to decode a content of said command register so as to execute an encoded BIST operation once with respect to each BIST operation per march element.

16. The processor-readable medium of claim 15 wherein said code further comprises code to reduce a test time via said slow speed signals and said information transfer protocol.

17. The processor-readable medium of claim 15 wherein said march element comprises at least one of: a plurality of BIST operations, an address sequencing information, and a data pattern.

18. The processor-readable medium of claim 15 wherein said code further comprises code to:
pulse a scan force signal in order to execute an operation for each march element once a content of said command register structure that includes a shorter BIST run is loaded;
receive a memory access command from said BIST controller by said BIST wrapper in accordance with said BIST sequence via said slow speed signals; and
execute a plurality of memory access and comparison operations.

19. The processor-readable medium of claim 15 wherein said code further comprises code to:
control a set of BIST through said BIST sequence by said BIST controller; and
read a plurality of status and diagnostic information from said BIST wrapper.

20. The processor-readable medium of claim 15 wherein said code further comprises code to separate said BIST sequence into at least one individual memory BIST operation during a BIST run phase by said BIST controller wherein said information is communicated to said BIST wrapper via said information transfer protocol.
